(19) United States
(12) Patent Application Publication
(10) Pub. No.: US 2025/0202517 A1
(43) Pub. Date: Jun. 19, 2025

(54) Method, Device and Apparatus for Generating In-Phase (I) and Quadrature- Phase (Q) Local Oscillator Signals

(71) Applicant: MMRFIC Technology Pvt. Ltd., Bangalore (IN)

(72) Inventors: Ganesan Thiagarajan, Bengaluru (IN); Saravanakumar Ganeshan, Bengaluru (IN)

(73) Assignee: MMRFIC Technology Pvt. Ltd., Bangalore (IN)

(21) Appl. No.: 18/875,726

(22) PCT Filed: Jul. 18, 2023
(86) PCT No.: PCT/IB2023/057294

§ 371 Date: Dec. 17, 2024

(30) Foreign Application Priority Data
Aug. 4, 2022 (IN) 202241044648

(51) Int. Cl. H04B 1/16; H03B 27/00

(52) U.S. Cl. CPC H04B 1/16; H03B 27/00

(57) ABSTRACT

According to an aspect, a method of generating an In-phase (I) and a Quadrature phase (Q) signal in an electronic system comprises receiving a first signal and a second signal of same frequency with different phase angle, adding the first and the second signal to generate a sum signal that is sum of the first and the second signal, subtracting the first signal from the second signal to generate a difference signal that is difference of the first and the second signal and providing the sum signal and the difference signal as the I signal and Q signal.

### CROSS REFERENCES TO RELATED APPLICATION

This application claims Priority from PCT application Number: PCT/IB2023/057294 filed on 18 Jul. 2023 that claim priority form Indian Patent Application number 202241044648 filed on Aug. 4, 2022 which is incorporated herein in its entirety by reference.

### TECHNICAL FIELD

Embodiments of the present disclosure relate to electronic system and more particularly relate to method, device and apparatus for generating in-phase (I) and quadrature-phase (Q) local oscillator signals.

### RELATED ART

A local oscillator signal (LO) is a signal that is often used in an electronic system to provide accurate timing reference, frequency reference etc. In several applications, two components of LO signals that are orthogonal to each other are employed. Thus, LO signals are generated as two signals that are orthogonal to each other, often referred to as in-phase signal (I) and quadrature phase signal (Q) (also referred to as orthogonal components and denoted as sin ωt and cos ωt, with ω representing angular frequency).

For example, in a communication system, orthogonal LO components are employed for extracting/generating I and Q components. These LO components required to be perfectly orthogonal to each other for both up-conversion and down-conversion, at least. However, as is known, analog components and circuits introduce amplitude and phase mismatch in the LO components.

FIG. 1 is a block diagram of a conventional zero-IF or direct conversion receiver, which extracts the I(t) and Q (t) from the composite modulated signal Y(t)=I(t) cos(ωt)−Q(t) sin (ωt), where w denotes the angular frequency of the carrier frequency. In practice, generating orthogonal LO component cos ωt and sin ωt, is marred by the imperfections such as amplitude mismatch and phase mismatch between the two arms 149A and 149B that is caused by analog circuits (comprising one or more of phase shifter 120, mixers 130A and 130B and filters 140A and 140B) which generate I and Q components from a common oscillator 110.

Conventionally, I and Q components are generated using poly-phase filters which generate the 90-degree phase shift on the cost signal. In another conventional technique, dividers are used to generate I and Q signal. For example, a reference clock signal is divided multiple times with its rising edge and/or falling edge as reference to generate I and Q signals. FIG. 2 illustrates conventional frequency divider techniques for generating I and Q signals. As shown there, the signal 210 represents the reference clock signal of frequency Fs. Signal 220 represents the Fs/2 signal with division performed with raising edge as reference. Signal 230 represents the Fs/2 signal with division performed with falling edge as reference. Signal 240 represents the Fs/4 signal that is used as I signal and Signal 250 represents the Fs/4 signal that is used as Q signal. Thus, when a desired frequency of the I and Q components is X, then, a 4X clock signal (VCO) is required to be implemented.

The conventional methods have multiple issues, especially when the LO frequency needs to be moved across a range and poly-phase filters are designed for center frequency in the band of operation. The later method needs higher frequency LO generation and the LO dividers introduce additional jitter (phase noise) and phase mismatch between the orthogonal components. These disadvantages are more pronounced when the electronic system is operative at high frequency ranges like 30-80 GHz. For example, 4×VCO is difficult to implement at high carrier frequencies such as RF, mmWave and Tera-hertz bands. Further, 2×VCO demands 50% duty cycle while typical duty cycle is in the range of 45-55%. Poly-phase filters have limited bandwidth and never generate perfect 90 degree offset across a range of frequencies. The performance/accuracy changes with power, voltage and temperature (PVT). Clock dividers demands high power (for ensuring good phase noise).

### SUMMARY

According to an aspect, a method of generating an In-phase (I) and a Quadrature phase (Q) signal in an electronic system comprises receiving a first signal and a second signal of same frequency with different phase angle, adding the first and the second signal to generate a sum signal that is sum of the first and the second signal, subtracting the first signal from the second signal to generate a difference signal that is difference of the first and the second signal and providing the sum signal and the difference signal as the I signal and Q signal.

According to the aspect, the amplitude of one of the sum signal and the difference signal is adjusted to reduce the amplitude mismatch due to operation of addition and subtraction. According to yet another aspect the amplitude of the first signal and second signal is made same before providing to the adder and the subtractor. For example, using a slicer before the sum and difference signal computation.

According to yet another aspect, a device providing In-phase (I) and a Quadrature phase (Q) signal comprises a signal source providing a reference signal, a phase shifter configured to shift the phase of the reference signal to generate a phase shifted reference signal, a gain controller adjusting amplitude of the reference signal, an adder adding the reference signal and the phase shifted reference signal and a subtractor subtracting the reference signal from the phase shifted reference signal, wherein, the output of the adder and the subtractor representing the I and Q signals respectively. Also a first and a second slicer configured to set the amplitude of the outputs of the adder and the subtractor equal. According to another aspect, the signal source is an voltage controlled oscillator and the phase shifter is a delay line providing adding a time delay to the reference signal.

### BRIEF DESCRIPTION OF DRAWINGS

FIG. 1 is a block diagram of a conventional zero-IF or direct conversion receiver.

FIG. 2 illustrates conventional frequency divider techniques for generating I and Q signals.

FIG. 3 is an example environment in which several aspects of the present invention may be seen.

FIG. 4A is a block diagram illustrating the manner in which I and Q signals are generated in one embodiment.

FIG. 4B is a graph illustrating the operations of the blocks 410-440.

FIG. 4C is a block diagram illustrating the manner in which amplitude mismatch may be eliminated in an embodiment.

FIG. 5 is device illustrating the generation of I and Q signals in one embodiment.

FIG. 6 is a device providing the I and Q signals in an alternative embodiment.

FIGS. 7A and 7B are circuit diagrams respectively illustrating the manner in which adder and subtractor may be implemented in one embodiment.

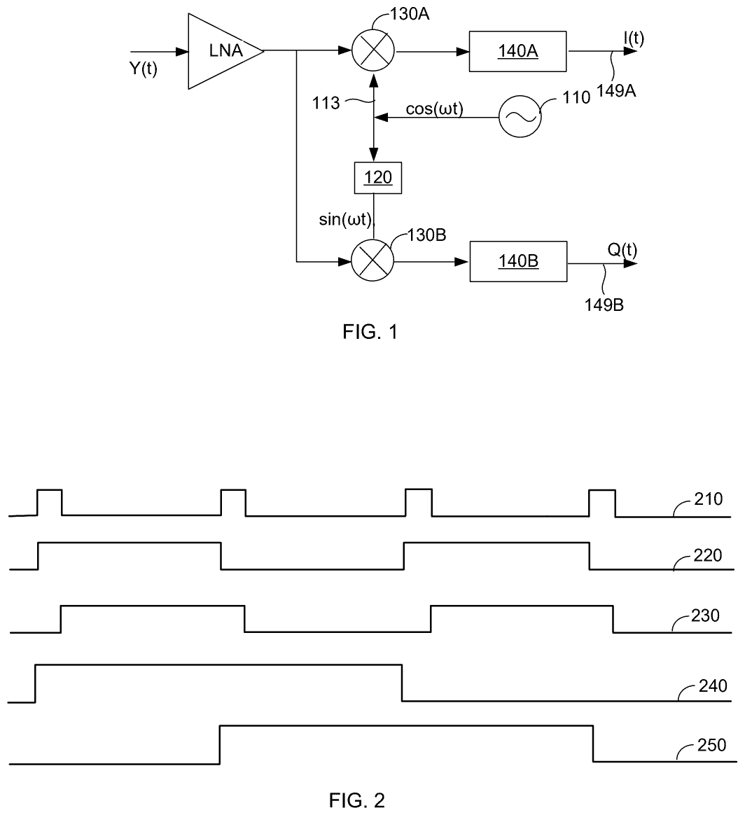

### DETAILED DESCRIPTION OF THE PREFERRED EXAMPLES

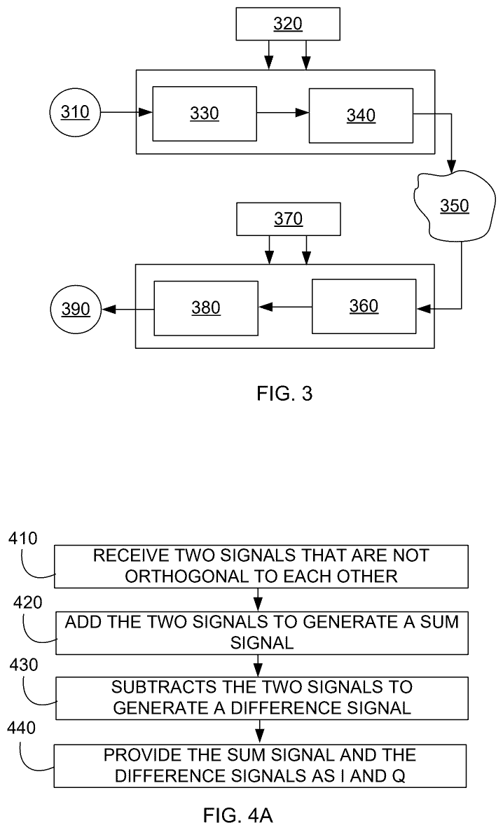

FIG. 3 is an example environment in which several aspects of the present invention may be seen. The environment 100 is shown comprising a signal source 310, I and Q generator 320, modulator 330, transmitter 340, channel 350, receiver 360, I and Q generator 370, demodulator 380, and output device 390. Each element is further described below.

The signal source 310 provides an information signal for processing and transmission. The signal source may comprise voice, audio, image, pictures, video, radar signal, etc. The signal source may provide the information signal in a frequency band based on the nature of the information. For example, the microphone as a signal source may provide voice signal in the frequency range 1-4 KHz, a video camera may provide the video signal in the frequency range of MHz. The signal source may provide the information signal in digital or analog form. Not limiting anything, the signal source may represent output of any electronic device.

The modulator 330 modulates the information signal using I and Q signals received from I and Q generator 320. The modulator may perform signal modulation such as QPSK and/or any other modulation techniques. In an alternative embodiment, the modulator may also comprise up-convertor, mixer and other signal processing circuitry operative to process the information signal using I and Q signals. The modulator may be implemented using digital, analog circuitry and/or combination thereof.

The transmitter 340 transmits the modulated signal received from the modulator 330 over channel 350. The transmitter 340 may comprise RF signals processor, filters, amplifiers, digital to analog convertor, up convertor, antennas etc. The channel 350, propagate signal received from the transmitter 340. The channel may comprise, wireless channels and wired cable channels capable of propagating the signal received from 340 to the receiver 360 with or without degradation.

The receiver 360 receives a signal from the channel 350 and performs several signal conditioning operations such as filtering, amplification, down converting etc. The receiver may comprise, receiving antenna, low noise amplifier, band pass filter, down convertor, mixer, analog to digital convertor for example, that are selectively deployed for converting the received signal to a signal suitable for processing and extracting the information. The signal conditioned by the receiver 360 is provided to the demodulator 380.

The demodulator 380 demodulates the received signal using I and Q signal received from the generator 370. In one embodiment, the demodulator 380 is operative in conjunction with the modulator 330. The demodulated signal is provided to output device 380. The output device 380 may comprise, memory device, display device, media player etc. In one embodiment, the elements 330-380 are operative complying to communications standards such as 4G and 5G, for example. In an alternative embodiment, the elements 330-380 are implemented as a radar system operative to detect one or more objects. In a yet another embodiment, the elements 330-380 are implemented in parts with elements 330 and 340 are operative independently. Similarly, the elements 360 and 380 are operative independently to detect gestures and other signals.

The I and Q generator 320 and 370 provide I and Q reference signal with reduced phase and amplitude mismatch. In other words, the I and Q generator 320 and 370 provide I and Q signals that are orthogonal to each other. As a result the transmitter section comprising modulator 330 and transmitter 340 are able to modulate the signal more precisely with less modulation/transmitter error/noise. Similarly, the receiver section 360 and 380 extract the signal with reduced error due to the reduced amplitude and phase error in the I and Q signals. The manner in which I and Q generator (320 and/or 370) generates the I and Q signal is further described below.

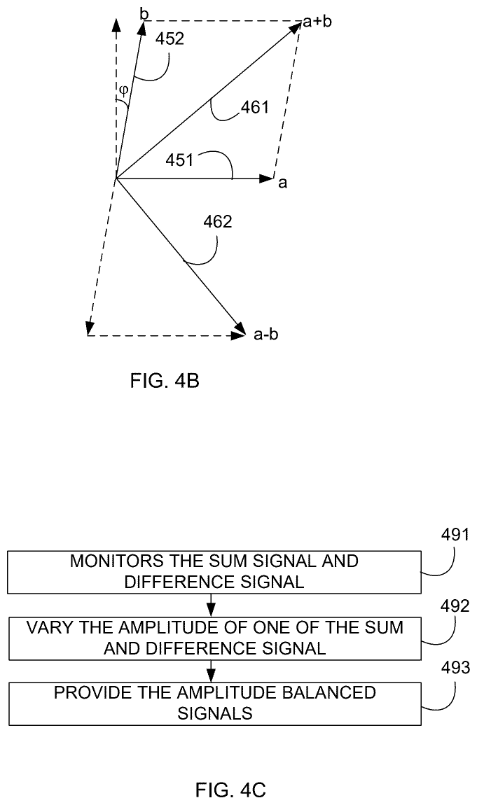

FIG. 4A is a block diagram illustrating the manner in which I and Q signals are generated in one embodiment. In the block 410, the I and Q generator 320 receives two signals that are not orthogonal to each other. For example the two signals, namely signal A and signal B may be of same frequency but of different phase. In one embodiment, the amplitude of the signal A and B are same. For example, the signal A and signal B are processed to match the equal amplitude and/or signal A and B may be derived from same signal source to have same amplitude.

In the block 420, the I and Q generator 320 adds the two signals to generate a sum signal that is sum of signal A and B. In the block 430, the I and Q generator 320 subtracts the two signals (one signal from the other) to generate a difference signal that is difference of signal A and B. In the block 440, the I and Q generator 320 provides the sum signal and the difference signals as I and Q signals respectively (that is one of them as I component and other as Q component). The operations of the blocks 410-440 are further illustrated below.

FIG. 4B is a graph illustrating the operations of the blocks 410-440. As shown there, the vectors 451 and 452 represents the two signals (for example Signal A and B) received in the block 410. The signal/vectors 451 and 452 may be represented as \vec{a}=cos ωt and \vec{b}=sin(ωt−φ). The vectors 461 represents the sum of the signals 451 and 452, that is the result of the add operation performed by the block 420. The add operation may be represented as: i₁(t)=\vec{a}+\vec{b}=cos ωt+sin(ωt−φ)=cos ωt(1−sin φ)+sin ωt cos φ. That is the vector 461 corresponds to the i₁(t).

Similarly, the vector 462 represents the difference of the signals 451 and 452, the result of subtraction operation performed in the block 430. The subtraction operation may be represented as: q₁(t)=\vec{a}−\vec{b}=cos ωt−sin (ωt+φ)=cos ωt(1+sin φ)−sin ωt cos φ. That is the vector 462 corresponds to the q₁(t). It may be seen that since integration of their product over one period gives:

$$IQMM = {\int }_{0}^{T} {i}_{1} ( t ) {q}_{1} ( t ) dt$$

$$IQMM = ( 1 - {sin}^{2} φ ) {\int }_{0}^{T} {( cos ω t )}^{2} d t - {cos}^{2} φ {\int }_{0}^{T} {( sin ω t )}^{2} d t = 0 ,$$

q₁(t) and i₁(t) are perfectly orthogonal to each other and the orthogonality is independent of the phase mismatch between the input signals 451 and 452.

In one embodiment, the I and Q generator 320 may further calibrate the amplitude of the signal q₁(t) and i₁(t). It may be seen that, after removing the phase error as in blocks 410-440, the resulting signals q₁(t) and i₁(t) may have experienced change in their amplitude. For example, the RMS powers of the phase corrected orthogonal signals q₁(t) and i₁(t) changes with the value of p. That is, the RMS value of i₁(t), represented as i_{1,rms} is (1−sin φ) by relation:

$${i}_{1 , rms} = {( 1 - sin φ )}^{2} {\int }_{0}^{T} {( cos ω t )}^{2} d t + {cos}^{2} φ {\int }_{0}^{T} {( ω t )}^{2} d t = ( 1 - sin φ ) ,$$

Similarly the RMS value of q₁(t), represented as q_{1,rms} is (1+sin φ) by relation:

$${q}_{1 , r m s} = {( 1 + sin φ )}^{2} {\int }_{0}^{T} {( cos ω t )}^{2} d t + {cos}^{2} φ {\int }_{0}^{T} {( sin ω t )}^{2} d t = ( 1 + sin φ )$$

Thus, the depending on the value of φ, the generated signals q₁(t) and i₁(t) may have different amplitude values.

The difference in the amplitude (amplitude mismatch) due to addition and subtraction operation may be represented as:

$${i}_{2} ( t ) = \vec{a} + \vec{b} = cos ω t + βsin ( ω t - φ ) = cos ω t ( 1 - βsinφ ) + βsinω t cos φ$$

and q₂(t)=\vec{a}−\vec{b}=cos ωt−β sin(ωt−φ)=cos ωt(1+β sin φ)−β sin ωt cos φ, in that, β is the amplitude mismatch factor (ratio of the amplitudes of the sum and difference signal). It may be noted that, this can result in a phase mismatch between the sum and difference signal which will disturb their orthogonality even if the inputs are perfectly orthogonal. Hence, the I and Q generator 320 may perform amplitude correction after generating q₁(t) and i₁(t) or may adjust the amplitude of the input signal to achieve perfect orthogonality and amplitude matched I and Q signal. The manner in which the amplitude may be adjusted in an embodiment is described in further detail below.

FIG. 4C is a block diagram 400A illustrating the manner in which amplitude mismatch between the I and Q signal may be eliminated in an embodiment. In the block 491, the I and Q generator 320 monitors the sum signal and difference signal received from block 420 and 430. In one embodiment, the I and Q generator may monitor sum signal \vec{a}+\vec{b} and the difference signal \vec{a}−\vec{b} to check if they are orthogonal and their amplitude is matched. For example, the IQ mismatch between the two may be represented as IQMM=(1−β² sin² φ)∫₀^{T}(cos ωt)²dt−(β cos φ)²∫₀^{T}(sin ωt)²dt. Adding and subtracting β² in the scale factor of first integration, the IQMM may be further represented as: IQMM=(1−β²)∫₀^{T}(cos ωt)²dt≠0 when β≠1. Accordingly, in the block 491 the I and Q generator 320 may monitor IQMM value.

In block 492 the I and Q generator 320 varies the amplitude of one of the signal received by the block 410 (that is cos ωt and sin(ωt−φ)). In one embodiment, the I and Q generator 320 may adjusted the amplitude of one the signal to achieve IQMM=0 in the relation above. The amplitude in one of the signal (Signal A and Signal B) may be adjusted using technique such as finite amplitude control, until the relation IQMM=(1−β²)∫₀^{T} (cos ωt)²dt becomes zero over a time period T or multiple of time period nT. In block 493 the I and Q generator 320 provides the amplitude balanced Orthogonal signals for further processing.

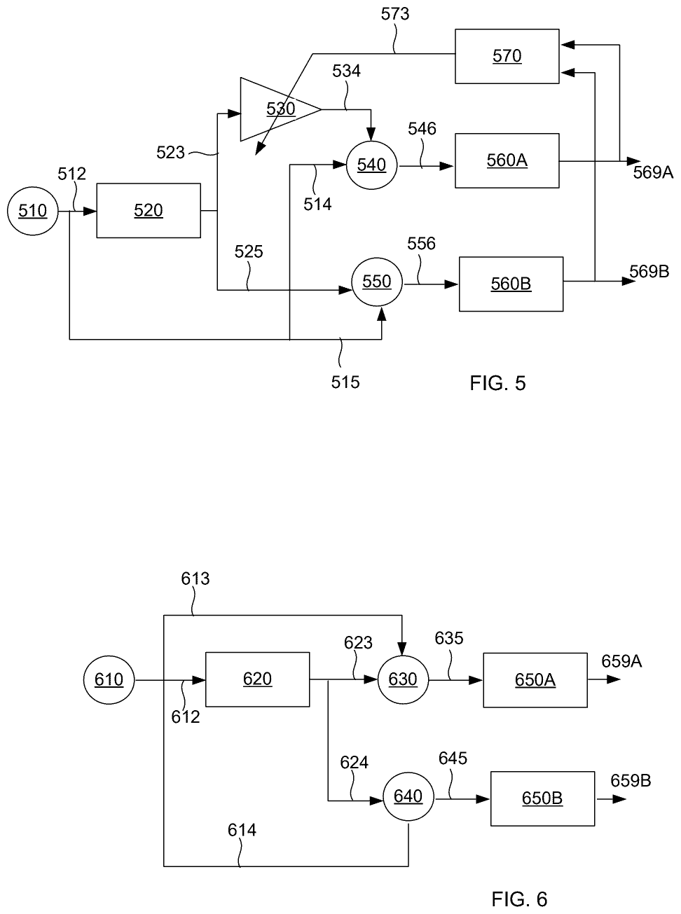

FIG. 5 is device illustrating the generation of I and Q signals in one embodiment. The device 500 is shown comprising signal source 510, phase shifter 520, gain controller 530, adder 540, subtractor 550, slicer 560A and 560B, and calibrator 570. Each element is further described below.

The signal source 510 provides the reference signal for generating I and Q signals. The signal source 510 generates a cosine wave reference signal of desired frequency (using phase locked loop, for example). The desired frequency of the reference signal source 510 may be in the base band frequency, RF frequency etc. In one embodiment, the frequency of the reference signal is in the range of 1-80 GHz. The generated reference signal is provided on path 512, 514 and 515.

The phase shifter 520 receives the reference signal on path 512 and shifts the phase of the signal by an angle φ. In one embodiment, the angle φ may be nearly 90 degrees. The phase shifted signal from the phase shifter 520 is provided on paths 523 and 525. The gain controller 530 adjusts the gain of the phase shifted signal received on path 523. In that the gain of the gain controller is controlled through the control signal received on path 573 from the calibrator 570. The gain adjusted signal is provided on path 534.

The adder 540 adds the signal received on paths 534 and 514. That is the adder receives the reference signal from the signal source 510 and the corresponding phase shifted and amplitude adjusted signal from the gain controller 530. The adder 540 generates the sum of the two signals and is provided on path 546.

Similarly, the subtractor 550 subtracts the signal received on paths 525 and 515. That is the subtractor receives the reference signal from the signal source 510 and the corresponding phase shifted signal from the phase shifter 520. The subtractor 550 generates the difference of the two signals and is provided on path 556. The slicer 560A and 560B together operate to remove the amplitude difference in the signal received on path 546 and 556. In one embodiment, the slicers 560A and 560B may compare the amplitude of the signal with a threshold (for example as in amplitude clipper or Schmitt Trigger) and provide a fixed amplitude signal at the respective output paths 569A and 569B.

The calibrator 570 receives the I and Q signal on path 569A and 569B and monitors the amplitude and phase of the signal. The calibrator may adjust the gain of the gain controller 530 until the I and Q signal on path 569A and 569B are orthogonal and matched in amplitude. Accordingly the adder and subtractor are operative to provide phase corrections required for perfect orthogonality between I and Q signal, and the calibrator and gain controller are operative to match the amplitude of I and Q signal.

FIG. 6 is a device providing the I and Q signals in an alternative embodiment. The device 600 is shown comprising voltage controlled oscillator (VCO) 610, delay 620, adder 630, subtractor 640 and slicers 650A and 650B. Each element is further described below.

The VCO 610 provides a reference signal for generating the I and Q signals. The reference signal may be in the frequency range 10-80 GHz. The reference signal is provided to both adder and subtractor 630 and 640 on path 613 and 614 respectively. The delay 620 receives the reference signal on path 612 to add a time delay to the reference signal. The delay 620 may be implemented as delay line (signal path that is longer than the path 613 and 614 enough to cause the time delay matching the fraction of the wavelength of the reference signal, which is natural in integrated circuits and PCB layouts. Accordingly, the delayed reference signal is provide to both adder 630 and subtractor 640 on path 623 and 624 respectively. The adder 630 adds the reference signal and delayed reference signal respectively received on paths 613 and 623 to generate a signal that is sum of the two signals (simply referred to as sum signal) and provided on path 635. Similarly the subtractor 640 subtracts the reference signal and delayed reference signal respectively received on paths 614 and 624 to generate a signal that is difference of the two signals (simply referred to as difference signal) and provide on path 645. The slicers 650A and 650B calibrate the amplitude of the sum signal and the difference signal received on path 635 and 645 respectively. The amplitude corrected and phase corrected orthogonal I and Q signals are provided as output of the slicer 650A and 650B on path 659A and 659B. It may be appreciated that, since the adder and subtractor receives the signals that is from same source, their amplitude are same thus, the output of the adder and subtractor are orthogonal to each other. Any mismatch in the amplitude at the output of adder and subtractor is matched by the slicers 650A and 650B without requiring the calibrator.

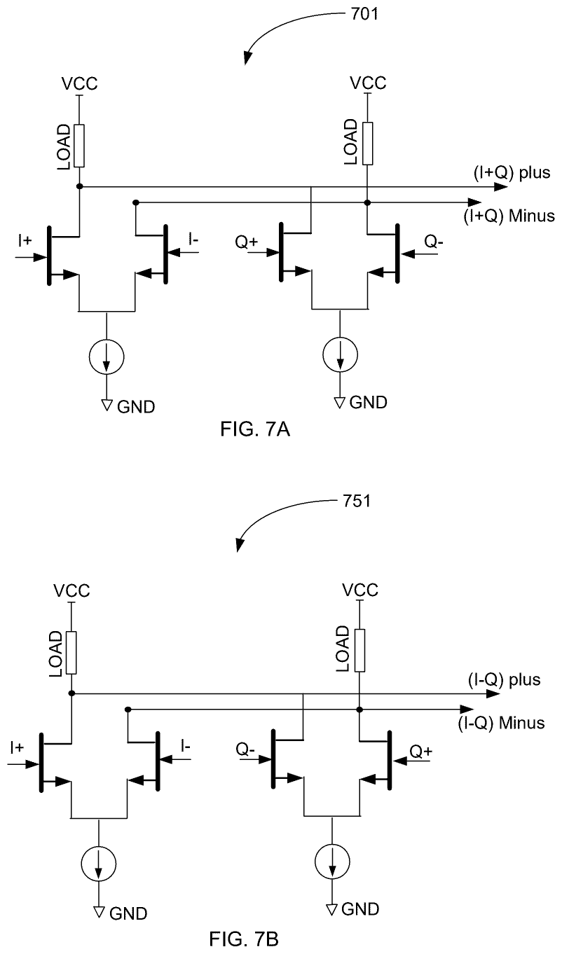

FIGS. 7A and 7B are circuit diagrams respectively illustrating the manner in which adder and subtractor may be implemented in one embodiment. As shown there the adder 701 and subtractor 751 is shown comprising the transistors, constant current sources and loads. In that, the transistors are configured receive differential inputs and provide differential outputs. The observable difference in the adder 701 and subtractor 751 is the manner in which the differential Q signal (Q− and Q+) are coupled to the transistors pair. That is the swap of the Q+ and Q− in the subtractor circuit 751 compared to that of adder circuit 701. Since the adder and subtractor circuits are identical except for the swap of the Q+ and Q− inputs, both can be made identical using currently available matching methods. This example is only given for illustration, which uses NMOS transistors and current source. Further, the circuits 701 and 751 may be implemented using PMOS, BJT, Fin-FET, or combinations of PMOS and NMOS, with or without explicit current source. In yet another alternative embodiment, one may combine both circuits (701 and 751) in a combined circuit. The load also can be any load comprising resistive, inductive, or a combination of resistive, inductive and capacitive loads. The technique described in the sections above, that is the orthogonal LO components generation method and device from the imperfect components is robust against phase mismatch between the input LO components. The amplitude mismatch induced IQMM is calibrated out easily. The technique may be employed for input LO components generated directly or using the divided clock.

Due to the above implementation, the tight circuit specifications for the polyphase filter which generates the 90-degree component may be relaxed. Since it is independent of the phase mismatch between the two input components, the generated LO components remain orthogonal over long frequency range before it must be calibrated. This proves to be useful where wide bandwidth of operation is needed. The amplitude mismatch correction can be precisely controlled over large bandwidth of operation. Hence, the complexity of the circuits is reduced and the re-calibration needs to be done across PVT (process, voltage, temperature) variations less frequently.

It may be appreciated that, generating I and Q using any prior technique with phase error may employ the techniques disclosed in the above sections to say adding and subtracting the conventionally generated I and Q and subtracting generate new I and Q that is free from phase error.

While various embodiments of the present disclosure have been described above, it should be understood that they have been presented by way of example only, and not limitation. Thus, the breadth and scope of the present disclosure should not be limited by any of the above-discussed embodiments but should be defined only in accordance with the following claims and their equivalents.

What is claimed is:

1. A method of generating an In-phase (I) and a Quadrature phase (Q) signal in an electronic system comprising:
receiving a first signal and a second signal of same frequency with different phase angle;
adding the first and the second signal to generate a sum signal that is sum of the first and the second signal;
subtracting the first signal from the second signal to generate a difference signal that is difference of the first and the second signal; and
providing the sum signal and the difference signal as the I signal and Q signal.

2. The method of claim 1, wherein amplitude of one the sum signal and the difference signal is adjusted to reduce the phase mismatch.

3. The method of claim 2, wherein amplitude of the first signal is varied until the amplitude of the sum and the difference signals are same and are orthogonal to each other.

4. The method of claim 2, wherein the amplitude and phase of the sum and the difference signal is monitored until the relation: ∫₀^{T}i₁(t)q₁(t) dt=(1−sin²φ)∫₀^{T} (cos ωt)²dt−cos² φ∫₀^{T}(sin ωt)²dt is set to zero value, wherein the i₁(t)=\vec{a}+\vec{b}=cos ωt+sin(ωt−φ)=cos ωt (1−sin φ)+sin ωt cos φ and q₁(t)=\vec{a}−\vec{b}=cos ωt−sin (ωt+φ)=cos ωt(1+sin φ)−sin ωt cos φ, in that the i₁(t) and q₁(t) representing the sum and difference signal.

5. A device providing In-phase (I) and a Quadrature phase (Q) signal comprising:
a signal source providing a reference signal;
a phase shifter configured to shift the phase of the reference signal to generate a phase shifted reference signal;
a gain controller adjusting amplitude of the reference signal;
an adder adding the reference signal and the phase shifted reference signal; and
a subtractor subtracting the reference signal from the phase shifted reference signal,
wherein, the output of the adder and the subtractor representing the I and Q signals respectively.

6. The device of claim 5, wherein the gain controller adjusting the amplitude of the reference signal meeting the relation: IQMM=(1−β²)∫₀^{T}(cos ωt)²dt=0, wherein β is the amplitude mismatch factor and cos ωt is the reference signal.

7. The device of claim 6, further comprising a first and a second slicer configured to set the amplitude of the outputs of the adder and the subtractor equal.

8. The device of claim 6, further comprising a first and a second slicer configured to set the amplitude of the inputs of the adder and the subtractor equal.

9. The device of claim 5, wherein the signal source is an voltage controlled oscillator and the phase shifter is a delay line providing adding a time delay to the reference signal.
